(19) United States
(12) Patent Application Publication
(10) Pub. No.: US 2025/0046748 A1
(43) Pub. Date: Feb. 6, 2025

(54) SOLDER BONDING ON AuSn BASIS WITH LOW BONDING TEMPERATURE

(71) Applicant: ams-OSRAM International GmbH, Regensburg (DE)

(72) Inventors: Klaus MUELLER, Pettendorf (DE); Holger KLASSEN, Regenstauf (DE); Georg PIRZER, Schwandorf (DE)

(21) Appl. No.: 18/716,114

(22) PCT Filed: Dec. 2, 2022
(86) PCT No.: PCT/EP2022/084154

§ 371 Date: Jun. 3, 2024

(30) Foreign Application Priority Data
Dec. 3, 2021 (DE) 10 2021 131 940.4

(51) Int. Cl. H01L 23/00

(52) U.S. Cl. CPC H01L 24/32; H01L 24/29; H01L 24/83; H01L 2224/29111; H01L 2224/29144; H01L 2224/29155; H01L 2224/29166; H01L 2224/32225; H01L 2224/32503; H01L 2224/8381

(57) ABSTRACT

The present invention relates to an electronic component comprising: a substrate, an optoelectronic component, a first intermetallic layer consisting of tin and nickel, a second intermetallic layer comprising tin and titanium, a third intermetallic layer comprising tin and gold, whereby the amount of tin and gold in the third intermetallic layer is approximately the same. The invention also relates to a method of manufacturing an electronic component and the use of an electronic component.

The present application claims the priority of the German patent application DE 10 2021 131 940.4 of Dec. 3, 2021, the disclosure of which is hereby incorporated by reference in its entirety.

The invention relates to an electronic component, a method for manufacturing an electronic component, an electronic component manufactured according to a method according to the invention and the use of an electronic component.

### DESCRIPTION

Au—Sn-based chip connections are frequently used in optoelectronics. These soldering processes require high process temperatures of over 280° C. due to the melting point of the solder material used. In many cases, these temperatures are critical for the processed opto semiconductors (e.g. lasers, UV-C LEDs, etc.) or for the substrates used. The process temperature can be reduced by the described invention, which on the one hand enables the processing of such temperature-sensitive materials, and on the other hand reduces the mechanical stresses that arise during cooling due to the different thermal expansion coefficients (CTE mismatch) of the materials in the component.

WO 2018/228891 A1 describes a solder joint in which a tin-rich primary melt reacts with a gold reservoir in the layer stack after breaking through a titanium barrier, resulting in isothermal solidification. The melting temperature of the tin-rich primary melt is reduced by adding indium. As the corresponding metallization layer is located on the very outside of the layer stack, a mixed oxide is formed on the surface, which consists at least partially of indium oxide. A covering (e.g. with a thin gold layer) could lead to the formation of high-melting intermetallic phases, which could affect the wetting behavior.

The task of the present invention was therefore to overcome the disadvantages of the prior art and to provide a new electronic component, a new method for manufacturing an electronic component and a new electronic component manufactured by a method according to the invention.

The problem of the present invention is solved by an electronic component according to claim 1, a method of manufacturing an electronic component according to claim 6, an electronic component according to claim 16 and the use of an electronic component according to claim 17. Advantageous further developments and embodiments are the subject of the dependent patent claims.

The object of the present invention is an electronic component comprising:
a substrate,
an optoelectronic component,
a first intermetallic layer consisting of tin and nickel,
a second intermetallic layer comprising tin and titanium,
a third intermetallic layer comprising tin and gold,
   whereby the amount of tin and gold in the third intermetallic layer is approximately the same.

In the context of the present invention, an electronic component is in particular an optoelectronic component. This can be understood to mean, for example, LED (light emitting diode) encapsulations, LED packages, LED modules, etc. An electronic component can also be a housing, in particular for sealing LEDs, wavelength converters or lasers. Preferably, the electronic component is an element for generating radiation or light.

According to the present invention, the electronic component comprises a substrate. The substrate may be a carrier, such as a lead frame, a plate (e.g. a printed circuit board), or a layer. Exemplary substrates can be lead frames made of copper, plates or printed circuit boards made of fiber-reinforced plastic or ceramic, or layers made of silicon or glass or sapphire.

Furthermore, the electronic component comprises an optoelectronic component. The optoelectronic component may be an LED or an arrangement of several LEDs, a chip, wavelength converters, such as phosphors in the form of crystals, quantum dots, powders, glasses, lasers, etc. A chip can be a layer sequence comprising a layer (e.g. InGaN) that is set up to emit electromagnetic radiation. Optoelectronic components are well known to those skilled in the art.

The electronic component comprises a first intermetallic layer. An intermetallic layer is a homogeneous phase of at least two metals. The composition and structure of the intermetallic phase can be defined in more detail in a phase diagram and described by a specific stoichiometric composition of the individual metals.

In the present case, the first intermetallic phase consists of tin (Sn) and nickel (Ni). “Consisting of” in connection with the first intermetallic phase means that the material content of foreign elements, i.e. elements, in particular metals, other than Sn and Ni, is in particular not higher than 20 at. %, preferably not higher than 10 at. %, more preferably not higher than 5 at. %, even more preferably not higher than 0.5 at. %. In other words, the first intermetallic phase is formed from a SnNi mixture.

In a preferred embodiment, the first intermetallic phase has no other elements, in particular no other metals (e.g. indium).

The first intermetallic layer preferably has a Niₓ Sn₁₋ₓ phase, where 0.3<x<0.6.

The first intermetallic phase may account for an average proportion in relation to the first, second and third intermetallic phases of less than 20 at. %, preferably less than 15 at. %, more preferably less than 10 at. %.

The electronic component further comprises a second intermetallic layer comprising tin (Sn) and titanium (Ti).

“Comprising Sn and Ti” in connection with the second intermetallic layer can mean that the material content of foreign elements, i.e. elements, in particular metals, other than Sn and Ti, is up to 20 at. %, preferably up to 10 at. %, more preferably up to 5 at. %. In one embodiment, the second intermetallic layer consists of Sn and Ti and has no significant foreign elements.

In one embodiment, the second intermetallic phase may comprise the elements tin, titanium and nickel. In a further embodiment, the second intermetallic phase comprises the elements tin, titanium and platinum. In a further embodiment, the second intermetallic layer comprises the elements tin, titanium, nickel and platinum.

The second intermetallic phase preferably has a Snₓ Ti₁₋ₓ phase, where 0.3>x>0.7. Alternatively, however, the second intermetallic phase can also have a Snₓ Ti_{y} Au_{1-x-y} phase, where 0<x<0.6 and 0<y<0.8 and x+y<1.

The second intermetallic phase can make up an average proportion in relation to the first, second and third intermetallic phase of less than 5 at. %, preferably less than 3 at. %, more preferably less than 1 at. %.

The electronic component further comprises a third intermetallic layer comprising tin (Sn) and gold (Au).

“Comprising Sn and Au” in connection with the third intermetallic layer can mean that the material content of foreign elements, i.e. elements, in particular metals, other than Sn and Au is up to 10 at. %, preferably up to 5 at. %, more preferably up to 1 at. %. In one embodiment, the third intermetallic layer consists of Sn and Au and has no significant foreign elements.

In one embodiment, the third intermetallic layer may comprise the elements tin, gold and nickel. In a further embodiment, the third intermetallic phase comprises the elements tin, gold and platinum. In a further embodiment, the third intermetallic layer comprises the elements tin, gold, nickel and platinum. In a further embodiment, the third intermetallic layer comprises the elements tin, gold and palladium.

The third intermetallic phase preferably has a Snₓ Au₁₋ₓ phase, where 0.45>x>0.7.

In one embodiment, the third intermetallic phase has a delta phase, but can also have a zeta or zeta′ phase.

The third intermetallic phase can make up an average proportion in relation to the first, second and third intermetallic phase of 80 at. %, preferably 50 at. %, more preferably 30 at. %.

According to the present invention, the amount of tin and gold in the third intermetallic layer is approximately equal.

“Approximately equal to” in the context of the third intermetallic layer means that the amount of tin is between 45 at. % to 55 at. %, preferably between 47 at. % to 53 at. %, more preferably between 49 at. % to 51 at. %. In this context, the amount of gold may be between 45 at. % to 55 at. %, preferably between 47 at. % to 53 at. %, more preferably between 49 at. % to 51 at. %. Exemplary embodiments of third intermetallic layers have 45 at. % Sn and 55 at. % Au, 47 at. % Sn and 53 at. % Au, 49 at. % Sn and 51 at. % Au. In one embodiment, “approximately equal” means that the amount of tin is 50 at. % and the amount of gold is 50 at. %. The amounts of tin and gold preferably add up to 100 at. %. In embodiments in which further elements are present in the third intermetallic layer, these amounts of material are also added and the sum of the elements present in the third intermetallic layer is added up to 100 at. %.

The amount of substance, which is denoted by “n”, indirectly indicates the number of particles in a portion of substance. The amount of substance can be calculated from n=M/m, where “M” is the molar mass in g/mol and “m” is the weight in g.

In one embodiment, the proportion by weight of tin in the third intermetallic layer is in the range from 33% to 42% by weight, preferably in the range from 36% to 40% by weight, more preferably in the range from 38% to 39% by weight, based on the total weight of the third intermetallic layer.

In one embodiment, the weight percentage of gold in the third intermetallic layer is in the range between 67 wt. % to 58 wt. %, preferably in the range between 64 wt. % to 60 wt. %, more preferably in the range between 62 wt. % to 61 wt. %, based on the total weight of the third intermetallic layer.

Further intermetallic or metallic layers can be arranged between the first, second and/or third intermetallic layer. “Between” the layers means that the further layer(s) at least partially separate(s) the existing layers from each other. If, for example, a further (inter)metallic layer is arranged between the first and second intermetallic layer, this (inter)metallic layer at least partially separates the first intermetallic layer from the second intermetallic layer so that they have no contact points with each other in this area. The same applies to the second and third intermetallic layers.

A further metallic layer can be arranged between the first intermetallic layer and the second intermetallic layer. For example, the further metallic layer may be a nickel layer, a titanium layer, a platinum layer, etc.

A further intermetallic layer can also be arranged between the first intermetallic layer and the second intermetallic layer. The further intermetallic layer may be a layer comprising nickel and titanium, a layer comprising nickel and platinum, or a layer comprising titanium and platinum, etc.

A further intermetallic layer can also be arranged between the second intermetallic layer and the third intermetallic layer. The further intermetallic layer may be a layer comprising gold and titanium, a layer comprising gold and tin, a layer comprising titanium and tin, a layer comprising gold, palladium and tin, etc.

In a preferred embodiment, the first intermetallic layer is adjacent to the substrate, i.e. the first intermetallic layer is in physical or electrical contact with the substrate, and the third intermetallic layer is adjacent to the optoelectronic component, i.e. the third intermetallic layer is in physical or electrical contact with the optoelectronic component. In some embodiments, a further metallic or intermetallic layer may be at least partially disposed between the first intermetallic layer and the substrate, or the third intermetallic layer and the optoelectronic component, thus physically or electrically separating the substrate from the first intermetallic layer in this region, or the optoelectronic component from the third intermetallic layer. In such embodiments, the second intermetallic layer is arranged between the first intermetallic layer and the third intermetallic layer. Here too, one or more (inter)metallic layer(s) can be arranged between the first intermetallic layer and the second intermetallic layer and the second intermetallic layer and the third intermetallic layer.

In an alternative embodiment, the first intermetallic layer is adjacent to the optoelectronic component, i.e. the first intermetallic layer is in physical or electrical contact with the optoelectronic component, and the third intermetallic layer is adjacent to the substrate, i.e. the third intermetallic layer is in physical or electrical contact with the substrate. In some of these embodiments, a further metallic or intermetallic layer may be at least partially disposed between the first intermetallic layer and the optoelectronic component, or the third intermetallic layer and the substrate, thus physically or electrically separating the optoelectronic component from the first intermetallic layer in this region, or the substrate from the third intermetallic layer. In such embodiments, the second intermetallic layer is arranged between the first intermetallic layer and the third intermetallic layer. Again, one or more (inter)metallic layer(s) may be disposed between the first intermetallic layer and the second intermetallic layer and the second intermetallic layer and the third intermetallic layer.

According to the embodiments mentioned, the optoelectronic component is connected to the substrate via the first intermetallic layer, the second intermetallic layer and the third intermetallic layer.

In one embodiment, the electronic component further comprises a cover layer. The cover layer may be glass, sapphire, etc. The cover layer may have a thickness of 100 μm to 500 μm, preferably from 150 μm to 350 μm, more preferably from 250 μm to 300 μm.

In a further embodiment, the electronic component further comprises a frame. The frame may be a socket, in particular a lateral socket. However, a frame can also mean a housing comprising a base and a side socket. A frame can be made of copper, aluminum oxide or aluminum nitride, for example.

In particular, a frame is present in embodiments in which the electronic component is a (ceramic) LED package or a (ceramic) laser package. Particularly in the case of laser packages that have a base plate (e.g. a ceramic base plate) and a housing (e.g. a ceramic housing), a design such as that specified here by a first, second and third intermetallic layer is advantageous. The first, second and third intermetallic layers described here make it possible to achieve optimum encapsulation, in particular airtight encapsulation.

Another object of the present invention is a method of manufacturing an electronic component, in particular an electronic component according to the present invention. A method according to the invention comprises the steps of:
Providing a substrate comprising a first metallic layer comprising gold,
Providing an optoelectronic component,
Providing a solder metal layer sequence comprising a second metallic layer consisting of tin, a third metallic layer, optionally a first barrier layer and a second barrier layer, wherein the second barrier layer is arranged between the second metallic layer and the third metallic layer.

According to the method of the present invention, a substrate comprising a first metallic layer comprising gold (Au) is provided. The substrate may be a substrate as described herein.

The first metallic layer can be in direct physical and/or electrical contact with the substrate. However, at least one further layer, preferably a metallic layer, may also be present between the substrate and the first metallic layer. If a further metallic layer is present between the substrate and the first metallic layer, these are preferably connecting layers that facilitate the bonding of the first metallic layer to the substrate. For example, this may be platinum or nickel.

In addition to gold, the first metallic layer can also comprise other elements, in particular metals. For example, in addition to gold, platinum and/or tin may also be present in the first metallic layer, whereby the material content of gold is greater than the material content of the sum of the other elements, if these are present.

The first metallic layer can have a thickness of 0.5 μm to 4 μm, preferably from 1 μm to 3 μm, more preferably from 1.5 μm to 2 μm.

In one embodiment, the substrate also comprises a barrier layer in addition to the first metallic layer. The barrier layer is preferably arranged on the side of the first metallic layer facing away from the substrate.

The method according to the invention further comprises the step of providing an optoelectronic component. The optoelectronic component is an optoelectronic component as described herein.

The method according to the invention further comprises the step of providing a solder metal layer sequence. The solder metal layer sequence comprises a second metallic layer consisting of tin, a third metallic layer, optionally a first barrier layer and a second barrier layer. The second barrier layer is arranged between the second metallic layer and the third metallic layer.

The solder metal layer sequence can thus have a second metallic layer, a third metallic layer and a second barrier layer between the second and third metallic layers.

In an alternative embodiment, the solder metal layer sequence may comprise a second metallic layer, a third metallic layer, a second barrier layer between the second and third metallic layers, and a first barrier layer adjacent to the second metallic layer on the side facing away from the second barrier layer. The first barrier layer is preferably present when the substrate has no barrier layer.

According to the invention, the second metallic layer consists of tin (Sn). In other words, preferably no other elements, in particular metals, are present in the second metallic layer. The material content of further elements (e.g. gold or indium) can be at most 15 at. %, preferably at most 7 at. %, more preferably at most 1 at. %, relative to the total material quantity of the second metallic layer. The second metallic layer can have a thickness of 0.5 μm to 4 μm, preferably from 1 μm to 3 μm, more preferably from 1.5 μm to 2 μm.

The solder metal layer sequence also includes a third metallic layer. The third metallic layer is preferably an oxidation protection. An oxidation protection is a compound or element that prevents oxidation, i.e. reaction with oxygen, of the underlying layers.

Exemplary third metallic layers may comprise gold, silver and/or platinum. Preferably, the third metallic layer comprises or consists of gold.

The third metallic layer can have a thickness of 15 nm to 135 nm, preferably from 30 nm to 100 nm, more preferably from 50 nm to 70 nm.

A second barrier layer is arranged between the second metallic layer and the third metallic layer. Preferably, the second barrier layer is arranged in such a way that the second metallic layer is completely physically and/or electrically separated from the third metallic layer. This means that the second barrier layer is preferably a continuous layer. The barrier layer can also be regarded as a temporary diffusion barrier in order to at least temporarily prevent a reaction between the second metallic layer and the third metallic layer.

The second barrier layer can comprise nickel, titanium or platinum. The second barrier layer can be an alloy of the metals mentioned or a pure metal layer. If the second barrier layer comprises an alloy, the alloy can comprise nickel and platinum, nickel and titanium, platinum and titanium, nickel and platinum and titanium.

In one embodiment, the second barrier layer comprises titanium. Preferably, the second barrier layer is a titanium layer.

According to one embodiment, the second barrier layer can have a thickness in the range from 3 nm to 15 nm, preferably in the range from 5 nm to 10 nm. The second barrier layer can also have a thickness in the range from 6 nm to 8 nm. Exemplary thicknesses of the second barrier layer are 5 nm, 7 nm, 9 nm, 10 nm, 13 nm and 15 nm.

The solder metal layer sequence may have a first barrier layer. The first barrier layer may be in physical and/or electrical contact with the second metallic layer on the side facing away from the second barrier layer. In an alternative embodiment, the first barrier layer is in physical and/or electrical contact with the first metallic layer on the side facing away from the substrate. The first barrier layer, like the second barrier layer, can be considered as a temporary diffusion barrier to at least temporarily prevent a reaction between the first metallic layer and the second metallic layer.

The first barrier layer can comprise nickel, titanium or platinum. The first barrier layer can be an alloy of the metals mentioned or a pure metal layer. If the first barrier layer comprises an alloy, the alloy may comprise nickel and platinum, nickel and titanium, platinum and titanium, nickel and platinum and titanium.

In one embodiment, the first barrier layer comprises titanium. Preferably, the first barrier layer is a titanium layer.

According to one embodiment, the first barrier layer can have a thickness in the range from 10 nm to 50 nm, preferably in the range from 20 nm to 40 nm. The first barrier layer can also have a thickness in the range from 25 nm to 30 nm. Exemplary thicknesses of the first barrier layer are 20 nm, 25 nm, 30 nm, 35 nm, 38 nm and 40 nm.

In one embodiment, a method according to the invention comprises applying the solder metal layer sequence to the first metallic layer, wherein a first barrier layer is present and the first barrier layer is disposed between the first metallic layer and the second metallic layer. In other words, the layer sequence in this embodiment would be: substrate-first metallic layer-first barrier layer-second metallic layer-second barrier layer-third metallic layer. In this embodiment, the solder metal layer sequence that is applied may comprise the first barrier layer, the second metallic layer, the second barrier layer and the third metallic layer, and the first barrier layer may be present on the first metallic layer.

Preferably, the first and/or the second barrier layer comprise titanium or consist of titanium. In one embodiment, a method according to the invention may further comprise applying the optoelectronic component to the solder metal layer sequence, wherein the optoelectronic component is applied directly to the third metallic layer. The optoelectronic component may be an optoelectronic component mentioned herein. In this embodiment, the layer sequence would be: substrate-first metallic layer-first barrier layer-second metallic layer-second barrier layer-third metallic layer-optoelectronic component.

The optoelectronic component can be applied by placing the optoelectronic component on the respective layer. It is particularly advantageous that no adhesives or other additional bonding agents are used in this process.

In an alternative embodiment, a method according to the invention may further comprise applying the optoelectronic component to the solder metal layer sequence, wherein the optoelectronic component is applied directly to the second metallic layer, or to the optionally present first barrier layer. Again, the optoelectronic component may be an optoelectronic component described herein. In this embodiment, the layer sequence would be: optoelectronic component-optional first barrier layer-second metallic layer-second barrier layer-third metallic layer.

In this alternative embodiment, the optoelectronic component can also be applied by placing the optoelectronic component on the respective layer. It is particularly advantageous that no adhesives or other additional bonding agents are used in this process.

In a further step, the alternative embodiment may further comprise applying the solder metal layer sequence and the optoelectronic component to the first metallic layer, wherein the third metallic layer is disposed between the first metallic layer and the second barrier layer. In this alternative embodiment, the layer sequence would be: substrate-first metallic layer-third metallic layer-second barrier layer-second metallic layer-optional first barrier layer-optoelectronic component.

A method according to the invention may further comprise applying a cover layer to the optoelectronic component. The cover layer may be a cover layer mentioned herein. Particularly preferably, the cover layer is a layer of glass.

The cover layer is preferably designed in such a way that it transmits radiation or light generated by the electronic component to the side facing away from the substrate or directs it in a specific direction.

A method according to the invention may further comprise the step of heating. The arrangement comprising the substrate, the first metallic layer, the solder metal layer sequence and the optoelectronic component can be heated.

Heating can cause a change in the aggregation states of the individual layers, i.e. the first metallic layer, the second metallic layer, the third metallic layer, the optional first barrier layer and the second barrier layer. In particular, heating is carried out in such a way that there is no change in the aggregation state of the substrate, the optoelectronic component and other optional layers and components (e.g. the cover layer, the frame, etc.).

Heating can also be understood as soldering.

Preferably, heating is carried out by applying heat to the side of the substrate. Alternatively, the heat can also be applied to the side of the optoelectronic component, in particular via a cover layer, if present. Alternatively, the heat can also be applied to both sides in parallel or alternately. Heating is carried out in particular by heat-emitting objects, such as heat plates, or by irradiation with high-energy radiation (e.g. by lasers or flash discharge lamps).

By heating the arrangement, the barrier layer closest to the heat-emitting object first becomes permeable. This causes the metallic layers adjacent to the barrier layer to come into contact with each other, resulting in the formation of a eutectic. When the eutectic melting temperature is reached, a melt comprising the metals of the neighboring metallic layers is formed. If, for example, the metallic layers are a gold layer and a tin layer and the barrier layer is a titanium layer, heating causes the titanium layer to become permeable and the gold layer comes into contact with the tin layer, forming a gold-tin eutectic. When the eutectic temperature is reached (e.g. >217° C.), a gold-tin melt is formed, which preferably solidifies isothermally in the delta phase during the further course of the process.

Through further heating, the additional barrier layer, if present, can become permeable and the neighboring metallic layer can come into contact with the eutectic formed first, whereby the metal of the neighboring metallic layer diffuses into the eutectic and thus the eutectic solidifies with the formation of intermetallic phases. If, for example, the additional barrier layer is a titanium layer, the titanium layer becomes permeable as a result of further heating. If the adjacent metallic layer is a gold layer and the eutectic is a gold-tin melt as described above, the gold in the gold layer diffuses into the gold-tin melt, whereby the melt solidifies to form at least one gold-tin phase. In particular, the gold-tin phase is a delta phase. In addition, the tin in the gold-tin melt or the gold-tin phase formed can also diffuse into the gold layer, forming at least one gold-rich gold-tin phase.

If no further barrier layer is present, i.e. only the second barrier layer is present, the melt comes into contact with the neighboring metallic layer, whereby the metal of the neighboring metallic layer diffuses into the eutectic and the eutectic solidifies, forming intermetallic phases. If, for example, the adjacent metallic layer is a gold layer and the eutectic is a gold-tin melt as described above, the gold of the gold layer diffuses into the gold-tin melt, whereby the melt solidifies with the formation of at least one gold-tin phase. In particular, the gold-tin phase is a delta phase. In addition, the tin in the gold-tin melt or the gold-tin phase formed can also diffuse into the gold layer, forming at least one gold-rich gold-tin phase.

The barrier layers prevent the individual metallic layers from reacting prematurely, which means that heating can be used to control a targeted reaction between the individual layers.

Typical temperatures for heating are 150° C. to 250° C., preferably 200° C. to 240° C., more preferably between 220° C. and 230° C.

It is particularly preferable for the individual layers to have a certain thickness in relation to each other. A defined composition of the individual intermetallic layers can be achieved by specifically selecting the thicknesses.

To form an intermetallic phase between the first metallic phase and the second metallic phase, the layer thickness ratio between the first metallic phase and the second metallic phase is preferably: 1:1 to 2:1, more preferably 0.6:0.4. In this embodiment, the first barrier layer is preferably arranged between the first metallic phase and the second metallic phase and has a thickness in the range from 10 nm to 50 nm, for example, preferably in the range from 20 nm to 40 nm.

The phase formed from the first metallic phase and the second metallic phase is preferably the third intermetallic phase in the manufactured electronic component. An electronic component according to the present invention is thus an intermetallic layer comprising tin and gold, the amount of tin and gold being approximately equal. Preferably, the third intermetallic layer is in the delta phase.

To form an intermetallic phase between the second metallic phase and the third metallic phase, the layer thickness ratio between the second metallic phase and the third metallic phase is preferably: 1:1 to 2:1, more preferably 0.6:0.4. In this embodiment, the second barrier layer is arranged between the second metallic phase and the third metallic phase and has a thickness in the range from 3 nm to 15 nm, preferably in the range from 5 nm to 10 nm, for example.

The layer formed from the second metallic layer and the third metallic layer is preferably the first intermetallic layer in the manufactured electronic component. An electronic component according to the present invention is thus an intermetallic layer consisting of tin and nickel.

As part of the process, an intermetallic layer can also be formed between the second metallic layer and the optionally present first or second barrier layer. In this case, an intermetallic layer comprising tin and titanium can be formed. Thus, in an electronic component according to the present invention, a second intermetallic layer comprising tin and titanium may be present.

A further object of the present invention is an electronic component manufactured according to a method according to the invention.

Another object of the present invention is the use of an electronic component according to the invention in laser applications, automotive lighting, general lighting, display applications, projection, etc.

Further advantageous embodiments and further embodiments of the invention result from the embodiment examples described below in conjunction with the figures.

Elements that are identical, similar or have the same effect are marked with the same reference symbols in the figures. The figures and the proportions of the elements shown in the figures should not be considered to be to scale. Rather, individual elements, in particular layer thicknesses, may be shown in exaggerated size for better visualization and/or understanding.

### FIGURES

FIG. 1 shows an SEM image of a section of a cross-section of an electronic component.

FIG. 2 shows an arrangement for manufacturing an electronic component.

FIG. 3a shows an arrangement in a method according to the invention.

FIG. 3b shows the structure of an electronic component.

FIG. 4a shows an arrangement in a method according to the invention.

FIG. 4b shows the structure of an electronic component.

FIG. 5 shows an embodiment of a method according to the invention.

FIG. 6 shows a phase diagram.

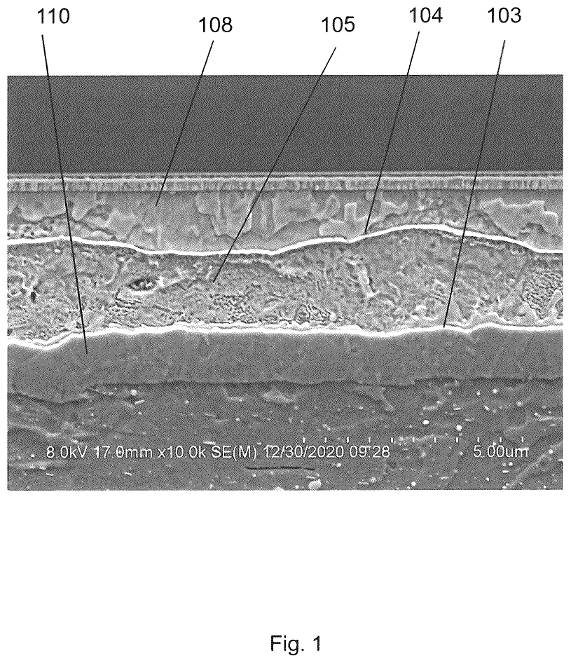

FIG. 1 shows a section of a cross-section of an electronic component. Layer 103 represents the first intermetallic layer, which consists of tin and nickel. Layer 104 represents the second intermetallic layer, which comprises tin and titanium. The proportion of tin can be variable and a pure titanium layer can also be adjacent as a barrier layer. Layer 105 forms the third intermetallic layer, which comprises tin and gold. The tin-gold layer shown is present as a delta phase. Layer 108 forms the first metallic layer comprising gold. The first metallic layer 108 can also partially contain or consist of gold-rich intermetallic Au—Sn phases (e.g. zeta or zeta′) due to diffused tin. The layer 110 forms the third metallic layer, which in the present case is a nickel layer.

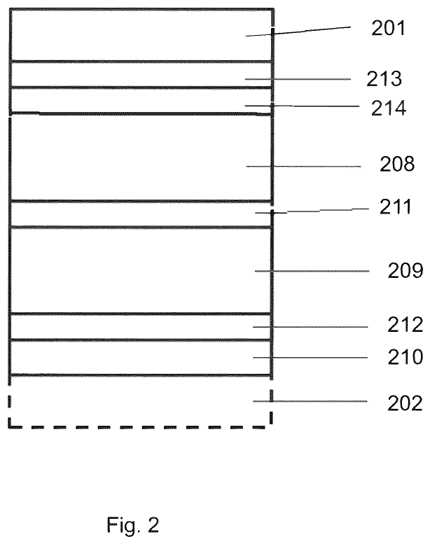

FIG. 2 shows an arrangement from which an electronic component can be produced after heating. A substrate 201 is shown in FIG. 2, whereby the substrate can be a carrier (e.g. a silicon carrier). Adjacent to the substrate 201 is a first optional layer 213, which may, for example, be a contact layer (e.g. Pt/Au). Furthermore, adjacent to layer 213 is a second optional layer 214, which may be a diffusion barrier (e.g. Ti/Pt). Adjacent to the second optional layer 214 is the first metallic layer 208, which comprises gold. In an exemplary embodiment, the layer 208 has a thickness of about 1.5 to 2 μm. The first barrier layer 211 is adjacent to the layer 208. In one embodiment, the barrier layer 211 is a titanium layer with a thickness in the range of 20 to 40 nm. The second metallic layer 209 is adjacent to the barrier layer 211. In one embodiment, the second metallic layer 209 may be a tin layer with a thickness of 1 to 2 μm. Adjacent to the second metallic layer 209, FIG. 2 shows a second barrier layer 112. The second barrier layer 112 can be a titanium layer with a thickness of 5 to 10 nm. A third metallic layer 210 adjoins the second barrier layer 112. The third metallic layer 210 may be an oxidation protection. An optoelectronic component 202 is shown in dashed lines adjacent to the third metallic layer 210. The layers 211, 209, 212 and 210 form the solder metal layer sequence. Preferably, in this embodiment, the first barrier layer 211 is significantly thicker than the second barrier layer 212. In particular, the first barrier layer 211 can control the lifetime during heating of the melt prior to isothermal solidification.

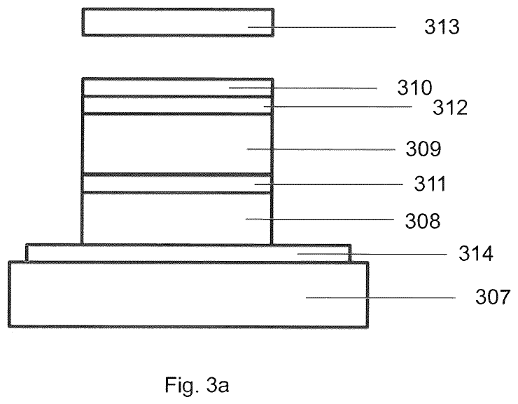

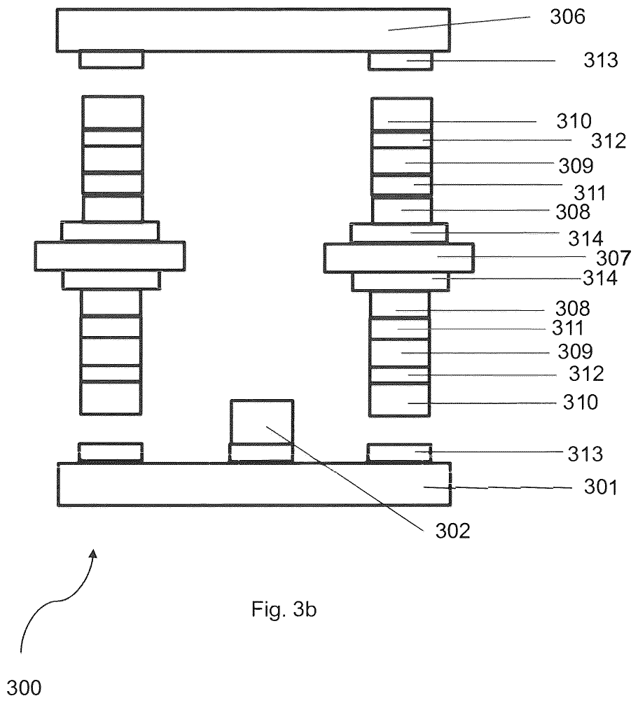

FIG. 3a shows a possible arrangement of layers in a method according to the invention for manufacturing an electronic component. FIG. 3a shows a section of FIG. 3b. Here, an optional second layer 314 is applied to a frame 307, with a first metallic layer 308 adjacent to it. Alternatively, it is also conceivable that instead of being applied to a frame 307, an optional second layer 314 is applied to a substrate 301, to which a first metallic layer 308 adjoins, and thus a layer arrangement as described herein in FIG. 3a is present. The first metallic layer 308 can have a thickness of 1.5 to 2 μm. A first barrier layer 311 is adjacent to the layer 308. The layer 311 can consist of titanium and have a thickness in the range of 20 to 40 nm. The second metallic layer 309 is adjacent to this. The layer 309 can be a tin layer with a thickness of 1 to 2 μm. The third metallic layer 310 is separated from the second metallic layer 309 by a second barrier layer 312. The second barrier layer 112 may be a titanium layer with a thickness in the range of 5 to 10 nm. The third metallic layer 313 can also be regarded as oxidation protection and prevent the second barrier layer from reacting with the oxygen in the environment. At some distance, FIG. 3a shows an optional first layer 313 that can be brought into contact with the solder metal layer sequence of layers 310, 312, 309 and 311. In the embodiment shown in FIG. 3a, the first barrier layer 311 is significantly thicker than the second barrier layer 312. The first barrier layer 311 can be used to control the lifetime of the melt produced during heating prior to isothermal solidification.

FIG. 3b shows an electronic component 300 with a substrate 301, an optoelectronic component 302, a first optional layer 313, a third metallic layer 310, a second barrier layer 312, a second metallic layer 309, a first barrier layer 311, a first metallic layer 308, a second optional layer 314, a frame 307 and a cover layer 306. The materials in FIG. 3b and the thicknesses of the individual layers can correspond to those in FIG. 3a. FIG. 3b shows one possibility of a hermetically sealed package.

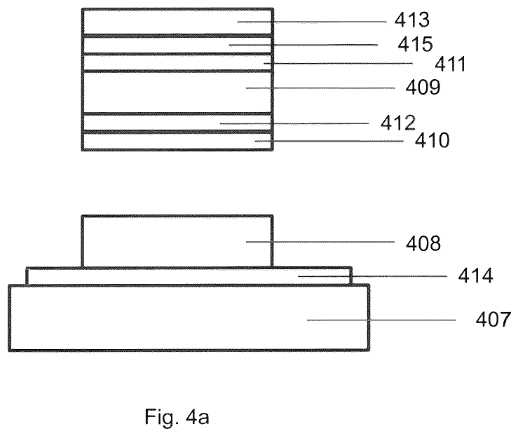

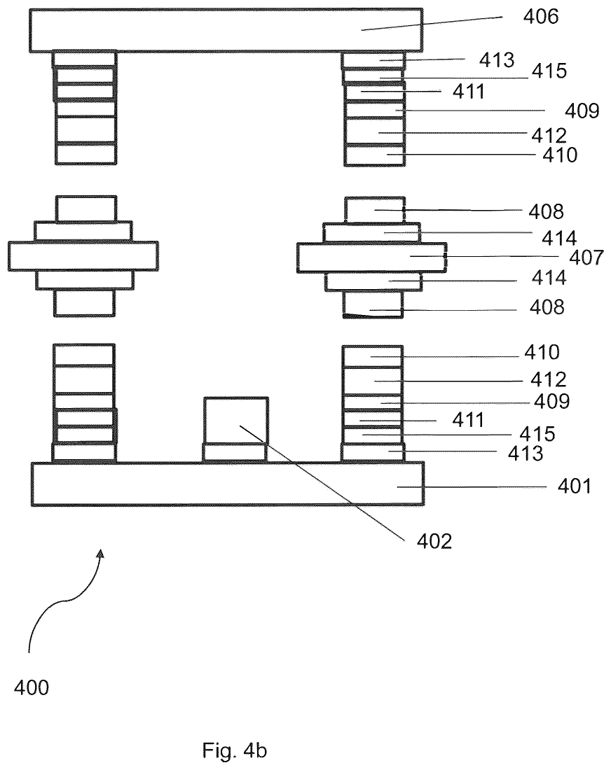

FIG. 4a shows a further possible arrangement of layers in a method according to the invention for manufacturing an electronic component. FIG. 4a shows a section of FIG. 4b. Here, an optional second layer 414 is applied to a substrate 401, adjacent to which a first metallic layer 408 is applied. Alternatively, it is also conceivable that instead of being applied to a frame 407, an optional second layer 414 is applied to a substrate 401, to which a first metallic layer 408 is adjacent and thus a layer arrangement as described herein in FIG. 4a is present. The first metallic layer 408 can have a thickness of 1.5 to 2 μm. Spaced from the layer 408 is a third metallic layer 410. The third metallic layer 410 can also be regarded as oxidation protection and prevent a reaction of the second metallic layer 409 with the oxygen in the environment. The layer 409 may be a tin layer with a thickness of 2 μm. The layer 412 is the second barrier layer that prevents the second metallic layer 409 from reacting with the third metallic layer 410 at room temperature. The first barrier layer 411 may comprise titanium and have a thickness of 10 nm. The first barrier layer 411 is optional in the arrangement shown.

Adjacent to the layer 411 is a third optional layer 415 (with a thickness of e.g. 100 nm), as well as an optional layer 413. The layer 413 may be a terminal metallization (e.g. CuNiAu). The layer 415 can be an intermediate Au layer. At some distance, FIG. 4a shows a third metallic layer 410, which can be brought into contact with the first metallic layer 408. In the embodiment shown in FIG. 4a, the first barrier layer 411 is significantly thicker than the second barrier layer 412.

FIG. 4b shows a structure of an electronic component 400 with a substrate 401, an optoelectronic component 402, a first optional layer 413, a third optional layer 415, a first barrier layer 411, a second metallic layer 409, a second barrier layer 412, a third metallic layer 410, a first metallic layer 408, a second optional layer 414, a frame 407 and a cover layer 406. The materials in FIG. 4b and the thicknesses of the individual layers may correspond to those in FIG. 4a. FIG. 4b shows one possibility of a hermetically sealed package.

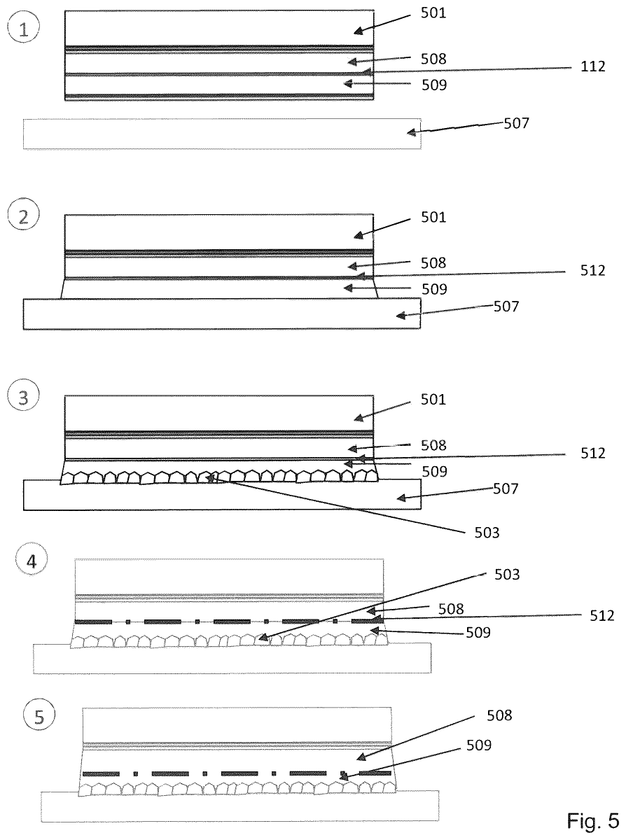

FIG. 5 shows an embodiment of a method according to the invention. In the first step, a layer sequence comprising a substrate 501, a first metallic layer 508 and a second metallic layer 509 is brought into the vicinity of a frame 507 (e.g. made of copper). The layers 508 and 509 are separated by a second barrier layer 512. In the second step, the frame 507 is brought into direct contact with the layer 509 and heating is started. In the third step, the material of the layer 509 melts and wets the surface of the frame 507, forming the first intermetallic layer 503 between the frame 507 and the molten layer 509. In the fourth step, the layer 512 becomes at least partially permeable so that the layers 508 and 509 come into contact with each other. As a result, the metal of the adjacent metallic layer 508 diffuses into the melt 509. Layer 503 shows the first intermetallic layer. In the final step 5, the melt from the layers 508 and 509 solidifies, forming intermetallic phases in an isothermal reaction, thus creating a solid and airtight bond between the components.

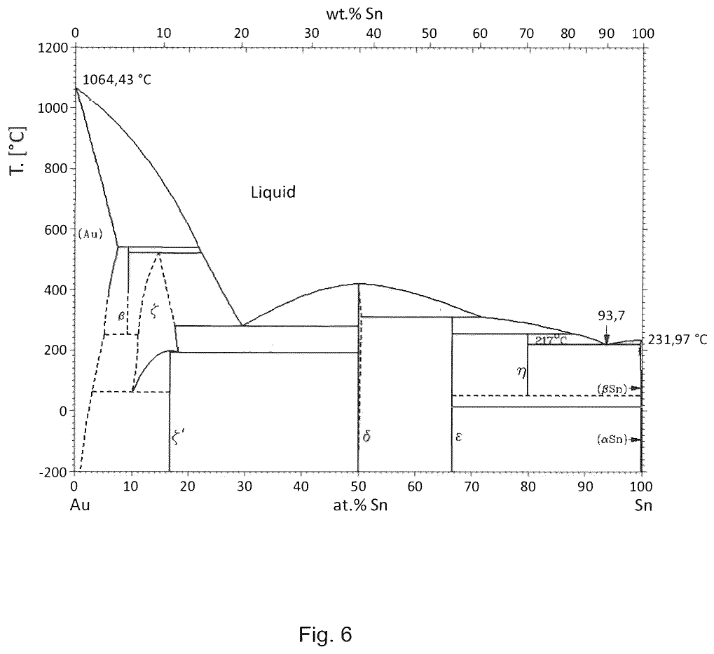

FIG. 6 shows a phase diagram of gold-tin alloys. The proportion of tin in atomic percent (at. %) or in weight percent (wt. %) is plotted on the x-axis and the temperature (Z) is plotted on the y-axis. As can be seen, the gold-tin alloy of the delta phase is formed (dashed line) from a tin content of 50 at. %. The delta phase therefore has a composition of the formula Snₓ Au₁₋ₓ with 0.45<x<0.7.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

List of reference symbols

| | |
|---|---|
| 300, 400 | electronic component |
| 201, 301, 401, 501 | substrate |
| 202, 302, 402 | optoelectronic component |
| 103, 503 | first intermetallic layer |
| 104 | second intermetallic layer |
| 105 | third intermetallic layer |
| 306, 406 | top layer |
| 307, 407, 507 | frame |
| 108, 208, 308, 408, 508 | first metallic layer |
| 209, 309, 409, 509 | second metallic layer |
| 110, 210, 310, 410 | third metallic layer |
| 211, 311, 411 | first barrier layer |
| 212, 312, 412, 512 | second barrier layer |
| 213, 313, 413 | optional first layer |
| 214, 314, 414 | optional second layer |
| 415 | optional third layer |

1. Electronic component comprising:
a substrate,
an optoelectronic component,
a first intermetallic layer consisting of tin and nickel,
a second intermetallic layer comprising tin and titanium,
a third intermetallic layer comprising tin and gold,
whereby the amount of tin and gold in the third intermetallic layer is approximately the same,
wherein the third intermetallic layer comprises a gold-tin alloy of the delta phase.

2. Electronic component according to claim 1, wherein the weight percentage of tin in the third intermetallic layer is in the range between 33 wt % to 42 wt %, preferably in the range between 36 wt % to 40 wt %, based on the total weight of the third intermetallic layer.

3. Electronic component according to claim 1, further comprising a cover layer.

4. Electronic component according to claim 1, further comprising a frame.

5. A method of manufacturing an electronic component according to claim 1, comprising:
Providing a substrate comprising a first metallic layer comprising gold,
Providing an optoelectronic component,
Providing a solder metal layer sequence comprising a second metallic layer consisting of tin, a third metallic layer, optionally a first barrier layer and a second barrier layer, the second barrier layer being arranged between the second metallic layer and the third metallic layer.

6. The method of claim 5, further comprising the first barrier layer and applying the solder metal layer sequence to the first metallic layer, wherein the first barrier layer is disposed between the first metallic layer and the second metallic layer.

7. The method according to claim 5, wherein the first barrier layer and/or the second barrier layer comprises titanium.

8. The method according to claim 5, wherein the first barrier layer has a thickness in the range from 10 nm to 50 nm, preferably in the range from 20 nm to 40 nm.

9. The method according to claim 5, wherein the second barrier layer has a thickness in the range from 3 nm to 15 nm, preferably in the range from 5 nm to 10 nm.

10. The method of claim 6, further comprising applying the optoelectronic component to the solder metal layer sequence, wherein the optoelectronic component is applied directly to the third metallic layer.

11. The method according to claim 5, further comprising applying the optoelectronic component to the solder metal layer sequence, wherein the optoelectronic component is applied directly to the second metallic layer, or to the optionally present first barrier layer.

12. The method of claim 11, further comprising applying the solder metal layer sequence and the optoelectronic component to the first metallic layer, wherein the third metallic layer is disposed between the first metallic layer and the second barrier layer.

13. The method according to claim 10, further comprising applying a cover layer to the optoelectronic.

14. The method according to claim 5, further comprising heating an assembly comprising the substrate, the first metallic layer, the solder metal layer sequence and the optoelectronic component.

15. Electronic component manufactured according to a method of claim 5.

16. Use of an electronic component according to claim 1 in laser applications, automotive lighting, general lighting, display applications and/or projection.

17. Use of an electronic component according to claim 15 in laser applications, automotive lighting, general lighting, display applications and/or projection.
